(19) United States
(12) Patent Application Publication
(10) Pub. No.: US 2026/0343704 A1
(43) Pub. Date: Oct. 29, 2026

(54) SYSTEMS AND METHODS FOR PROVIDING ADAPTIVE VOLTAGE LIGHTING

(71) Applicant: Brightwave Tech, LLC, Farmington, UT (US)

(72) Inventor: Gary Bret Millar, Farmington, UT (US)

(21) Appl. No.: 19/649,897

(22) Filed: Apr. 16, 2026

Related U.S. Application Data
(60) Provisional application No. 63/790,193, filed on Apr. 17, 2025.

(51) Int. Cl. H05B 45/355; G01R 19/04; G01R 19/165; G01R 19/175; G01R 25/04; H05B 45/34; H05B 45/48; H05B 45/10

(52) U.S. Cl. CPC H05B 45/355; G01R 19/04; G01R 19/16528; G01R 19/175; G01R 25/04; H05B 45/34; H05B 45/48; H05B 45/10

(57) ABSTRACT

Systems and methods for providing adaptive voltage lighting is provided. One embodiment includes receiving AC power, where the AC power includes a voltage portion and a current portion. These embodiments may determine at least one characteristic of the AC power, and determine whether the characteristic exceeds a predetermined threshold. In some embodiments, in response to determining that the characteristic exceeds the predetermined threshold, the characteristic may be used to determine a selected branch from a plurality of branches to route at least a portion of the AC power, where the selected branch creates an altered AC power to return the at least one characteristic to a level that does not exceed the predetermined threshold. Some embodiments may cause at least a portion of the altered alternating current power to illuminate at least one LED.

### CROSS REFERENCE

This application claims the benefit of U.S. Provisional Application Serial Number 63/790,193, filed Apr. 17, 2025, which is hereby incorporated by reference in its entirety.

### TECHNICAL FIELD

Embodiments provided herein generally relate to systems and methods for providing adaptive voltage lighting and, more specifically, to embodiments that can correlate voltage and current, as well as control for power spikes in a light emitting diode (LED) lighting array.

### BACKGROUND

Use of LED lighting has provided major advantages over incandescent and fluorescent lighting. Not only is energy savings a major advancement with LED lighting, but heat reduction, space reduction, and reliability have all been improved. While LED lighting has these advantages, problems may exist with LED lighting, such as phase displacement. Specifically, as a sinusoidal power wave is received and processed through electronic circuitry, the voltage portion of the power wave may become displaced from the current portion of the power wave. One consequence of this phase displacement is that real power may stay the same, but apparent power can increase. This often means that more current must flow to the device to deliver the same usable power. This may also reduce electrical efficiency and waste capacity for a building or other system provider. The offset phase displacement may also result in a lower power factor, which can cause issues with the utility providing the power. In some situations phase displacement may result in poor performance in the LEDs themselves.

Additionally, some LED lighting systems may receive power spikes that can create problems for a utility, damage the lighting system, create excess heat and costs, and/or create other problems. As such, a need exists in the industry for adaptive voltage lighting.

### SUMMARY

Systems and methods for providing adaptive voltage lighting is provided. One embodiment includes receiving AC power, where the AC power includes a voltage portion and a current portion. These embodiments may determine at least one characteristic of the AC power and determine whether the characteristic exceeds a predetermined threshold. In some embodiments, in response to determining that the characteristic exceeds the predetermined threshold, the characteristic may be used to determine a selected branch from a plurality of branches to route at least a portion of the AC power, where the selected branch creates an altered AC power to return the at least one characteristic to a level that does not exceed the predetermined threshold. Some embodiments may cause at least a portion of the altered alternating current power to illuminate at least one LED.

In another embodiment, a system for providing adaptive voltage lighting includes a zero cross detector for determining when a voltage portion and/or a current portion of AC power changes between positive and negative, phase correction circuitry that includes a plurality of circuit branches for reducing a phase displacement of the voltage portion and the current portion in the alternating current power, and an LED array coupled to the phase correction circuitry, the LED array including a plurality of LEDs to be illuminated. Some embodiments include a computing device that is coupled to the phase correction circuitry. The computing device may cause the adaptive voltage lighting system to utilize the zero cross detector to determine a first zero cross of the current portion of the alternating current power, where the first zero cross includes a first timing that the current portion changes between positive and negative and utilize the zero cross detector to determine a second zero cross of the voltage portion of the alternating current power, where the second zero cross includes a second timing that the voltage portion changes between positive and negative. In some embodiments, the computing device may be configured to determine the phase displacement by comparing the first timing with the second timing, determine whether the phase displacement meets a predetermined threshold, and in response to determining that the phase displacement meets the predetermined threshold, determine a selected circuit branch from the plurality of circuit branches, where the selected circuit branch creates an altered alternating current power to return the phase displacement to a level that is below the predetermined threshold. In some embodiments, the computing device may cause at least a portion of the altered alternating current power to illuminate at least one LED of the LED array.

In yet another embodiment, a system includes light emitting diode (LED) control circuitry that includes a plurality of LED branches for dividing the alternating current power during a power spike, a peak to peak detector that determines voltage levels of a plurality of voltage peaks on the voltage portion of the alternating current power, and an LED array coupled to the LED control circuitry, the LED array including a plurality of LEDs to be illuminated. Some embodiments include a computing device that is coupled to the LED control circuitry. The computing device may be configured to cause the adaptive voltage lighting system to determine, via the peak to peak detector, a measured value of the alternating current power, determine whether the measured value meets a threshold value, and in response to determining the measured value meets the threshold value, determining a selected LED branch of the plurality of LED branches to route at least a portion of the alternating current power, where the selected LED branch is selected to create an altered alternating current power to dissipate the power spike. In some embodiments, the computing device may cause at least a portion of the altered alternating current power to illuminate at least one light emitting diode (LED).

These and additional features provided by the embodiments of the present disclosure will be more fully understood in view of the following detailed description, in conjunction with the drawings.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1 depicts an adaptive voltage lighting system, according to embodiments provided herein;

FIG. 2 depicts phase correction circuitry, according to embodiments provided herein;

FIG. 3 depicts LED control circuitry, according to embodiments provided herein;

FIG. 4 depicts a graphical representation of phase displacement, according to embodiments provided herein;

FIG. 5A depicts a sinusoidal wave representing a voltage that may be received and/or process by the adaptive voltage lighting system, illustrating zero cross points, according to embodiments provided herein;

FIG. 5B depicts a rectified representation of the sinusoidal wave from FIG. 5A, further illustrating peak voltage and slope to predict peak voltage, according to embodiments provided herein;

FIG. 6 depicts a flowchart illustrating operation of adaptive voltage lighting, according to embodiments provided herein;

FIG. 7 depicts another flowchart illustrating adaptive voltage lighting, according to embodiments provided herein; and

FIG. 8 depicts a computing device adaptive voltage lighting, according to embodiments provided herein.

### DETAILED DESCRIPTION

Embodiments disclosed herein include systems and methods for providing adaptive voltage lighting. Some embodiments monitors and controls the LED lights’ performance by sampling the AC power inputs, both frequency of the sinusoidal wave and amount of voltage, adjusting the phase displacement and under/over voltage in delivering a consistent brightness, while protecting the circuitry. The systems and methods for providing adaptive voltage lighting incorporating the same will be described in more detail, below.

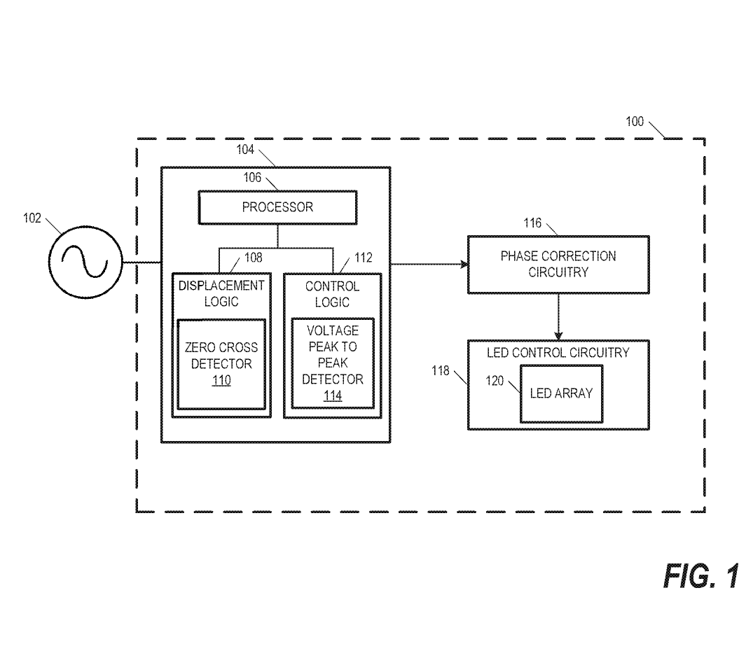

Referring now to the drawings, FIG. 1 depicts an adaptive voltage lighting system 100, according to embodiments provided herein. As illustrated, a power supply 102 may provide power to the adaptive voltage lighting system 100. As described in more detail below, the power supply 102 may provide sinusoidal or alternating current (AC) power to the adaptive voltage lighting system 100. While the power that is provided by the power supply 102 is typically phase aligned, sometimes the power received may include a phase displacement. In some situations, components within the adaptive voltage lighting system 100 may cause the current and voltage phases to become displaced. Additionally, in some embodiments, the power supply 102 may provide power spikes and/or other undesirable anomalies in the power signal.

The adaptive voltage lighting system 100 may include a computing device 104. The computing device 104 may include a processor 106 (and/or microcontroller, depending on the embodiment), which is coupled to displacement logic 108. Despite being depicted as software, in practice the displacement logic 108 may include hardware, software, and/or firmware and may be configured for determining features (e.g., frequency, phase, amplitude, zero cross) of a voltage signal received from the power supply 102, as well as features of a current signal received from the power supply 102. The zero cross of each of the voltage signal and the current signal may be determined via a zero cross detector 110. The zero cross detector 110 may include and/or be coupled with an oscilloscope and/or other measurement device hardware for measuring the input power, as well as software and/or firmware for determining the features. Upon determining the features, the displacement logic 108 may determine the phase displacement between the voltage and the current. If the displacement is greater than a predetermined threshold, the displacement logic 108 may cause the computing device 104 to instruct phase correction circuitry 116 to correct the phase displacement, as described in more detail below.

Also coupled with the processor 106 is control logic 112. The control logic 112 may include hardware, software, and/or firmware for managing LED output, based on various factors, such as a dimming instruction, a power spike, etc. The control logic 112 may include voltage peak to peak detector 114, which may include or be coupled with an oscilloscope and/or other measurement device hardware (in some embodiments, the same hardware that is part of the zero cross detector 110). The voltage peak to peak detector 114 may additionally include logic for measuring and/or predicting a plurality of voltage peaks of the received alternating current power. The control logic 112 may utilize this data to determine if there is a power spike. If there is a power spike that exceeds a predetermined voltage threshold, the control logic 112 may cause the computing device 104 to instruct LED control circuitry 118 to activate one or more LEDs of an LED array 120 (which may include a plurality of LEDs), as described in more detail below.

As will be understood, while the displacement logic is depicted as including the zero cross detector 110 and the control logic 112 is depicted as including the voltage peak to peak detector 114, these are merely examples. Some embodiments may be configured with these as separate components.

Also provided in FIG. 1 are the phase correction circuitry 116, the LED control circuitry 118, and the LED array 120. While FIG. 1 depicts the phase correction circuitry 116 in series with the LED control circuitry 118 and the LED array 120, this is merely one example, as other configurations are also contemplated. As an example, some embodiments may be configured such that both the phase correction circuitry 116, the LED control circuitry 118, and/or the LED array 120 are directly coupled to the computing device 104 such as via a bus.

Regardless, the phase correction circuitry 116 may be configured to delay or advance voltage to reduce and/or eliminate the phase displacement. The LED control circuitry 118 may be configured to alter the LEDs that are activated at any given time. The LED array 120 may include one or more sets of one or more LEDs for illumination.

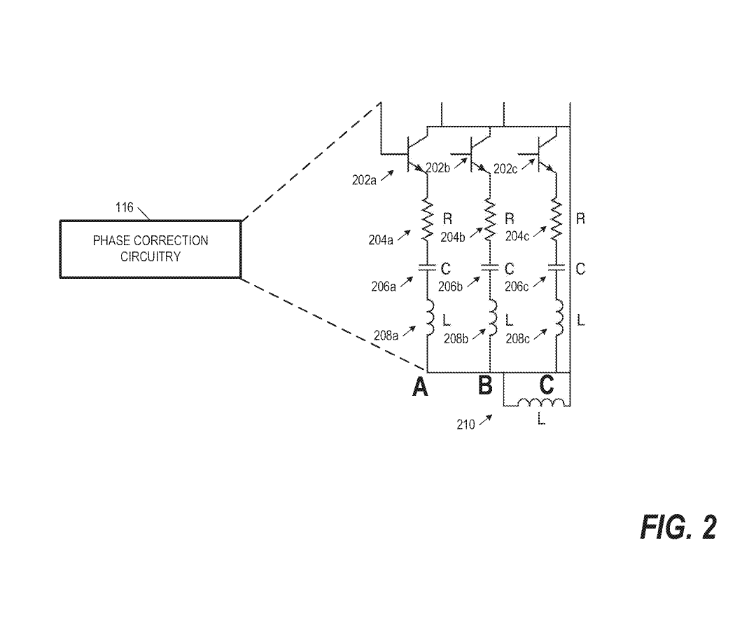

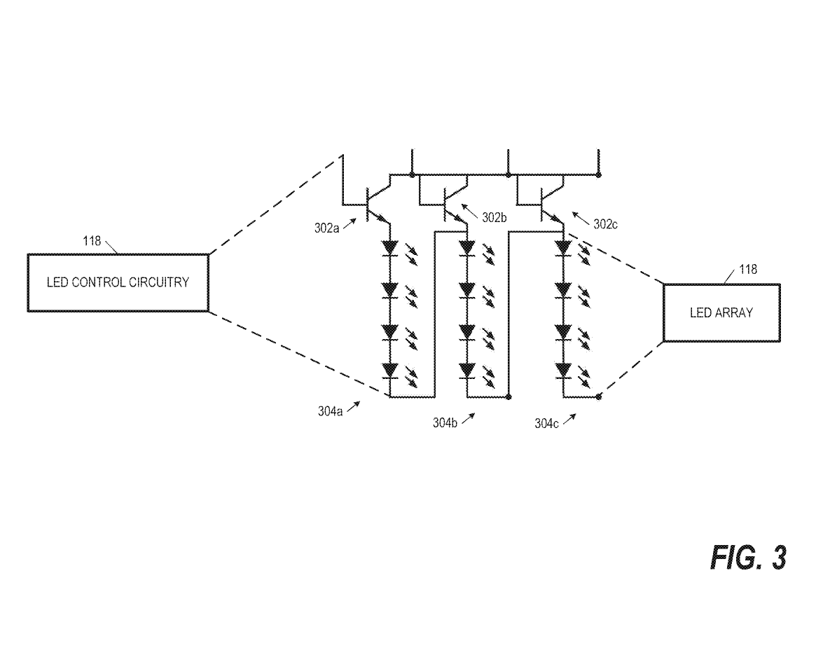

FIG. 2 depicts phase correction circuitry 116, according to embodiments provided herein. As illustrated, in FIGS. 2 and 3, embodiments provided herein may include a plurality of branches, such as a plurality of circuit branches (FIG. 2) and/or a plurality of LED branches (FIG. 3). As depicted in FIG. 2, the phase correction circuitry 116 may include a plurality of circuit branches. The circuit branches include transistors 202a, 202b, 202c. Each of the transistors 202 may be coupled in series with a resistor 204a, 204b, 204c, a capacitor 206a, 206b, 206c, and an inductor 208a, 208b, 208c. Completing the phase correction circuitry 116 is an inductor 210. The values of the resistors 204, capacitors 206, and inductors 208 may be determined based on predetermined criteria for correcting phase displacement. As an example, the resistor 204a may have a value of 220 ohms (Ω); the capacitor 206a may have a value of 3.662 microfarads (µf); and the inductor 306a may have a value of 318.3 millihenry (mH). The resistor 204b may have a value of 370 Ω; the capacitor 206b may have a value of 4.8 µf; and the inductor 208b may have a value of 291 mH. The resistor 204c may have a value of 680 Ω; the capacitor 206b may have a value of 2.8 µf; and the inductor 208c may have a value of 200mH.

Specifically, if the voltage is lagging the current, routing the AC power through a branch with a higher inductance may be desired. If the voltage is leading the current, a higher capacitance may be desired to bring the voltage and current in line. If the voltage has a higher peak than the current, a higher resistance may be utilized.

In operation, the computing device 104 may detect phase displacement, as well as the amount of phase displacement and the direction of phase displacement (forward, backward, and/or amplitude). Additionally, the computing device 104 may determine whether the phase displacement meets or exceeds a predetermined displacement threshold. If the phase displacement meets or exceeds the predetermined displacement threshold, the computing device 104 may access a lookup table that indicates which branch (A, B, or C in FIG. 2) is best suited for correcting the phase displacement. As an example, if the current phase displacement indicates that the voltage leads current by two cycles per second, the computing device 104 may access the lookup table to determine that branch B (which has a higher capacitance) is best suited for correcting that phase displacement. Upon making that determination, the computing device 104 can route the power through that branch.

As an other example, if the capacitor 206a can reduce current lag by 2 cycles, but the capacitor 206b can reduce current lag by 6 cycles, branch B may include the inductor 208b that can dampen the capacitance offset to be 4 cycles. As such, each branch may be tailored for a predetermined function.

It should be understood that while three branches are depicted in FIG. 2, this is merely one example. Some embodiments may have more ore fewer circuit branches, depending on the particular embodiment. Additionally, it should be understood that the phase displacement may change over time and embodiments provided herein may be configured to repeatedly, periodically, and/or continuously monitor the power to ensure that phase displacement is maintained within an acceptable range.

FIG. 3 depicts LED control circuitry 118, according to embodiments provided herein. As illustrated, the LED control circuitry 118 may include transistors 302a, 302b, 302c, as well as the LED array 118, which includes LED strings 304a, 304b, 304c. Specifically, if the computing device 104 detects or predicts a power surge from the power supply 102, the computing device 104 may instruct the LED control circuitry 118 to utilize one or more of the branches of LED strings 304a, 304b, 304c, while maintaining the desired luminosity. In some embodiments, the computing device 104 may receive data regarding the power spike, including voltage peak, current peak, duration, etc. Based on this data, the computing device 104 may access a lookup table to recommend the desired LED string(s) 304.

As an example, if a power surge of 100% over a baseline or threshold is detected or predicted, the computing device 104 may access a lookup table to best fit the power surge. In this example, the lookup table may indicate that LED string 304b(which also utilizes LED string 304c) should be used to accommodate the power surge while maintaining desired luminosity. In some embodiments, the computing device 104 may recommend that LED string 304a is utilized, which includes LED strings 304a, 304b, and 304c. By activating a corresponding number of additional LEDs during a power spike, the brightness may remain the same because each LED is receiving the amount of current corresponding to the desired output.

It should be understood that while three branches are depicted in FIG. 3, this is merely one example. Some embodiments may more ore fewer LED branches, depending on the particular embodiment.

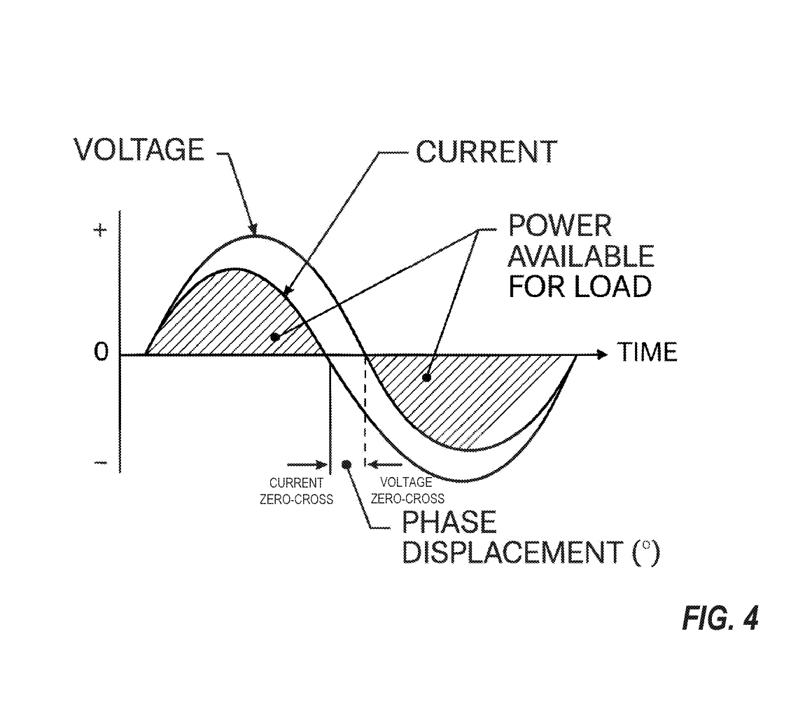

FIG. 4 depicts a graphical representation of phase displacement, according to embodiments provided herein. As illustrated, a power signal may be represented as a waveform and includes a voltage portion of alternating current power and a current portion of alternating current power. Additionally, as the power is received as an alternating current signal, the voltage and current are received as sinusoidal waves. While the power received is often configured with the voltage and current with aligned phases, sometimes the received power can be received with phase displacement or there are situations where a user’s electrical components can introduce the phase displacement. Specifically, the current may turn from positive to negative (or vice versa) at a first zero cross (the current zero-cross) and the voltage may turn from positive to negative (or vice versa) at a second zero cross (the voltage zero-cross). Regardless of how the phase displacement may be introduced, the example of FIG. 4 illustrates that the voltage not only has a higher voltage peak than the current, but when the time that the voltage crosses from positive to negative (the zero cross) is delayed from the current zero cross point. This difference in timing represents the phase displacement. As described above, this phase displacement can cause issues in performance, issues with the power provider, etc.

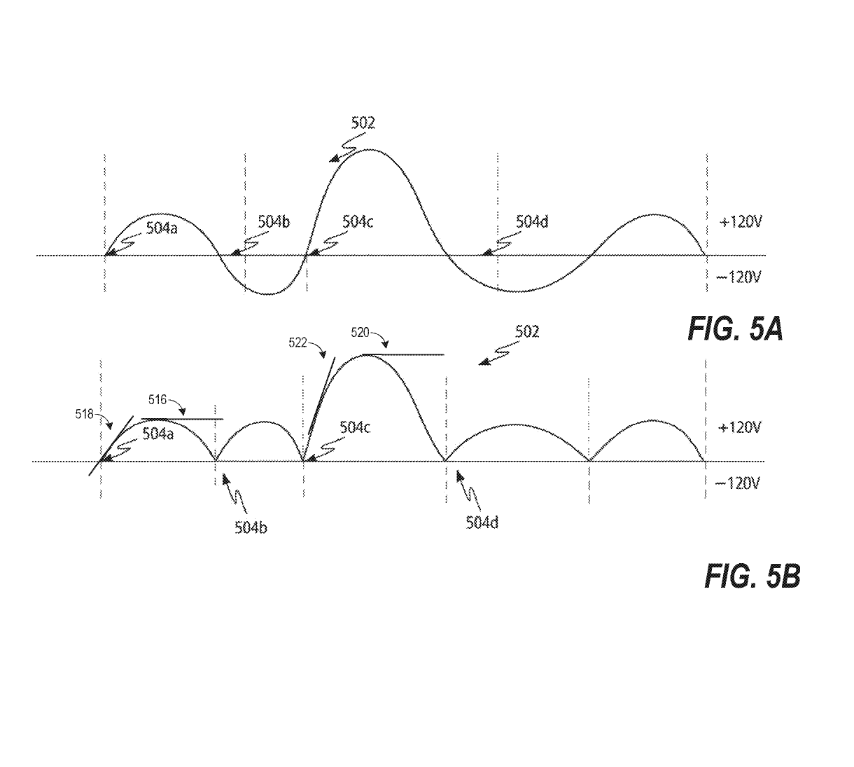

FIG. 5A depicts a sinusoidal wave 502 representing a voltage that may be received and/or process by the adaptive voltage lighting system 100, illustrating zero cross points, according to embodiments provided herein. As illustrated, the sinusoidal wave 502 may include at least one voltage peak that ranges from +120 Volts to -120 Volts and includes zero cross points 504a-504d. As described above, the zero cross points 504a-504d may be utilized to determine the phase displacement with the zero cross point of the current. However, with regard to power spike between zero cross point 504c and zero cross point 504d, quicker response to the power spike may be desired.

FIG. 5B depicts a rectified representation of the sinusoidal wave 502 from FIG. 5A, further illustrating peak voltage and slope to predict peak voltage, according to embodiments provided herein. As illustrated, the rectified representation flips the negative portions of the wave into positive, which may be first performed before predicting the power spike. Once the sinusoidal wave 502 is rectified, some embodiments may determine a baseline voltage peak (if not already known), as represented with tangential line 516. A measured value of each of the voltage peaks may then be performed. Each of the measured values may then be compared with the baseline (or threshold value) and if any of the measured values meets or exceeds a predetermined voltage threshold, the remaining portion of power spike mitigation may be performed.

In some embodiments, a quicker response may be desired. In these embodiments, the computing device 104 may be configured to calculate a derivative or slope at an earlier point of the waveform (represented by line 518 and line 522) to predict whether there is likely an upcoming power spike. As illustrated in FIG. 5B, the line 518 represents the slope of a baseline portion of the curve. Line 522 may also be taken to determine a predicted voltage peak and clearly has a greater slope than the line 518. If the difference in slope between line 518 and line 522 exceeds a predetermined slope threshold, the power spike mitigation mechanism disclosed here may be implemented.

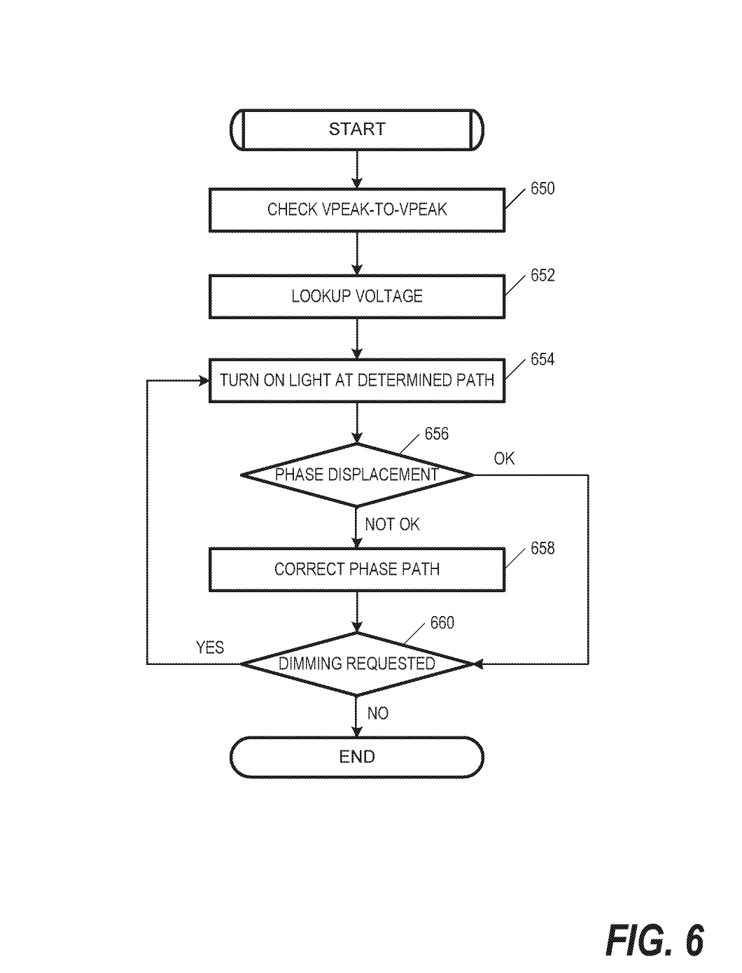

FIG. 6 depicts a flowchart illustrating operation of adaptive voltage lighting, according to embodiments provided herein. As illustrated in block 650, a peak to peak voltage may be determined. In block 652, the voltage may be looked up to determine the appropriate mitigation configuration. In block 654, an LED may be activated on a predetermined branch, as indicated by the lookup table. In block 656, a determination may be made regarding whether the phase displacement is acceptable. If the phase displacement is acceptable (e.g., at or below a predetermined displacement threshold), the process may proceed to block 660. If, at block 656, the phase displacement is not acceptable, at block 658, a phase path or branch may be selected to correct the phase displacement. At block 660, a determination may be made regarding whether dimming is requested. If so, the process returns to block 654. If not, the process may end.

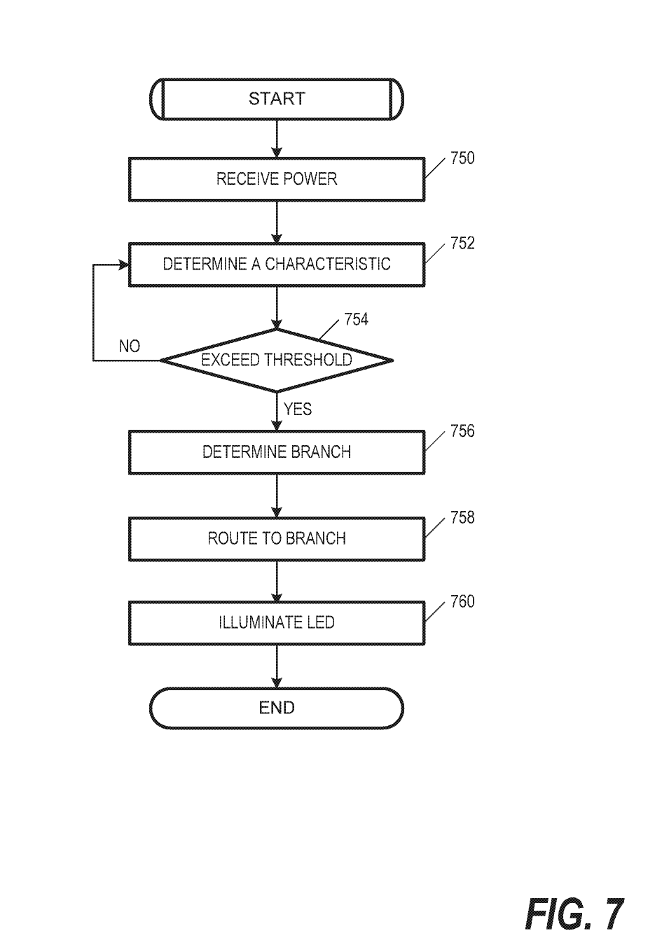

FIG. 7 depicts another flowchart illustrating operation of adaptive voltage lighting, according to embodiments provided herein. As illustrated in block 750, alternating current power may be received. In block 752, at least one characteristic of the received alternating current power may be determined. The characteristic may include the position of a first timing of a zero cross of the voltage portion of the alternating current power and a second timing of a zero cross of the current portion of the alternating current power. In some embodiments, the characteristic may include a voltage peak that indicates a voltage spike. In block 754, a determination may be made regarding whether the characteristic meets or exceeds a predetermined threshold. If not, process may return to block 752 to continue to monitor the alternating current power. If the characteristic meets or exceeds the predetermined threshold, a determination may be made regarding which of a plurality of branches is a selected branch (e.g., a selected circuit branch, a selected LED branch, etc.) to create altered alternating current power. As an example, if the characteristic relates to phase displacement, the determination may be made regarding which circuit branch (FIG. 2) to select. If the characteristic relates to a power spike, the determination may be made regarding which LED branch (FIG. 3) to select. In block 758, power may be routed to the selected branch. In block 760, at least one LED may be illuminated.

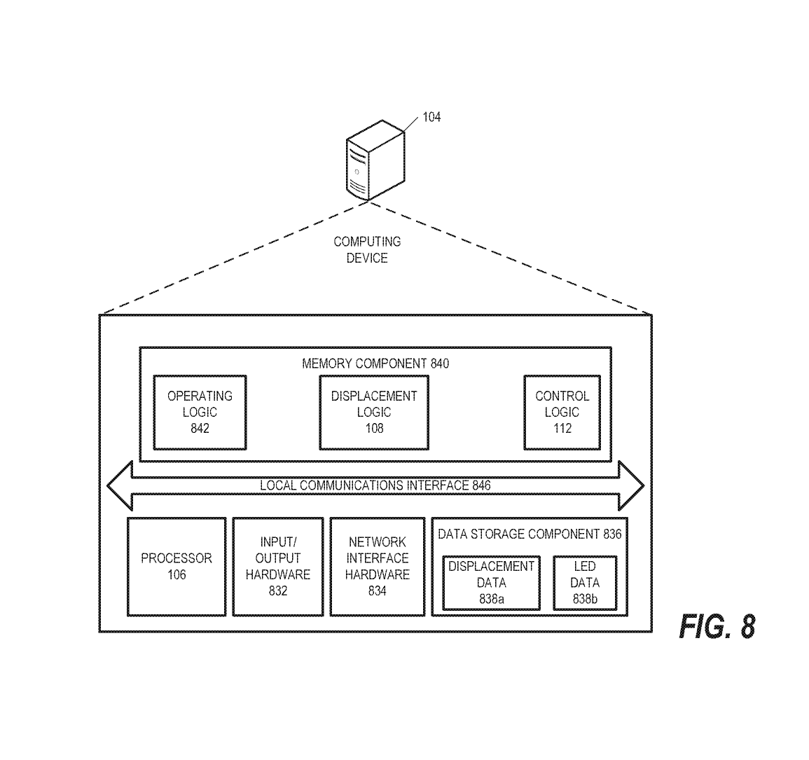

FIG. 8 depicts the computing device 104 of the adaptive voltage lighting system 100, according to embodiments provided herein. As illustrated, the computing device 104 includes a processor 106 (which may be configured as a microcontroller, depending on the embodiment), input/output hardware 832, a network interface hardware 834, a data storage component 836 (which stores displacement data 838a, LED data 838b, and/or other data), and a memory component 140. The memory component 140 may be configured as volatile and/or nonvolatile memory and as such, may include random access memory (including SRAM, DRAM, and/or other types of RAM), flash memory, secure digital (SD) memory, registers, compact discs (CD), digital versatile discs (DVD) (whether local or cloud-based), and/or other types of non-transitory computer-readable medium. Depending on the particular embodiment, these non-transitory computer-readable mediums may reside within the computing device 104 and/or external to the computing device 104.

The memory component 140 may store operating logic 842, the displacement logic 108 and the control logic 112. Each of these logic components may include a plurality of different pieces of logic, each of which may be embodied as a computer program, firmware, and/or hardware, as an example. A local interface 846 is also included in FIG. 8 and may be implemented as a bus or other communication interface to facilitate communication among the components of the computing device 104.

The processor 106 may include any processing component operable to receive and execute instructions (such as from a data storage component 836 and/or the memory component 140). As described above, the input/output hardware 832 may include and/or be configured to interface with speakers, microphones, and/or other input/output components.

The network interface hardware 834 may include and/or be configured for communicating with any wired or wireless networking hardware, including an antenna, a modem, a LAN port, wireless fidelity (Wi-Fi) card, WiMAX card, mobile communications hardware, transceiver, and/or other hardware for communicating with other networks and/or devices. From this connection, communication may be facilitated between the computing device 104 and other computing devices.

The operating logic 842 may include an operating system and/or other software for managing components of the computing device 104. As discussed above, the displacement logic 108 may be configured to cause the processor 106 to determine phase offset, determine actions to correct the phase offset, and cause the actions to occur, as provided herein. The control logic 112 may be configured to cause the processor 106 to detect spikes or other irregularities on received power and control operation of LEDs accordingly.

It should be understood that while the components in FIG. 8 are illustrated as residing within the computing device 104, this is merely an example. In some embodiments, one or more of the components may reside external to the computing device 104 or within other devices. It should also be understood that, while the computing device 104 is illustrated as a single device, this is also merely an example. In some embodiments, the displacement logic 108 and/or the control logic 112 may reside on different computing devices.

Additionally, while the computing device 104 is illustrated with the displacement logic 108 and the control logic 112 as separate logical components, this is also an example. In some embodiments, a single piece of logic may provide the described functionality. It should also be understood that while the displacement logic 108 and the control logic 112 are provided herein as the logical components, this is also an example. Other components may also be included, depending on the embodiment.

As illustrated above, various embodiments for providing adaptive voltage lighting are disclosed. These embodiments utilize a microcontroller or special purpose computer that may be integrated into a lighting system to reduce phase displacement, as well as dissipate power surges.

While particular embodiments and aspects of the present disclosure have been illustrated and provided herein, various other changes and modifications can be made without departing from the spirit and scope of the disclosure. Moreover, although various aspects have been provided herein, such aspects need not be utilized in combination. Accordingly, it is therefore intended that the appended claims cover all such changes and modifications that are within the scope of the embodiments shown and provided herein.

It should now be understood that embodiments disclosed herein include systems, methods, and non-transitory computer-readable mediums for providing adaptive voltage lighting. It should also be understood that these embodiments are merely exemplary and are not intended to limit the scope of this disclosure.

What is claimed is:

1. A method for providing adaptive voltage lighting comprising:
receiving, by an adaptive voltage lighting system, alternating current power, wherein the alternating current power includes a voltage portion and a current portion;
determining, by a computing device of the adaptive voltage lighting system, at least one characteristic of the alternating current power;
determining, by the computing device of the adaptive voltage lighting system, whether the at least one characteristic of the alternating current power exceeds a predetermined threshold;
in response to determining that the at least one characteristic of the alternating current power exceeds the predetermined threshold, using the at least one characteristic to determine a selected branch from a plurality of branches to route at least a portion of the alternating current power, wherein the selected branch creates an altered alternating current power to return the at least one characteristic to a level that does not exceed the predetermined threshold; and
causing, by the computing device of the adaptive voltage lighting system, at least a portion of the altered alternating current power to illuminate at least one light emitting diode (LED).

2. The method of claim 1, wherein the at least one characteristic relates to a phase displacement between the voltage portion and the current portion and wherein the predetermined threshold is a timing related to the phase displacement.

3. The method of claim 2, wherein the plurality of branches is configured as a plurality of circuit branches that each includes a resistor in series with a capacitor in series with an inductor.

4. The method of claim 2, wherein determining at least one characteristic includes determining a first zero cross of the current portion of the alternating current power wherein the first zero cross includes a first timing that the current portion changes between positive and negative and determining a second zero cross of the voltage portion of the alternating current power, wherein the second zero cross includes a second timing that the voltage portion changes between positive and negative.

5. The method of claim 4, wherein determining whether the at least one characteristic of the alternating current power exceeds the predetermined threshold includes determining the phase displacement by comparing the first timing with the second timing, and determining whether the phase displacement exceeds a predetermined displacement threshold.

6. The method of claim 1, wherein determining the selected branch includes accessing a lookup table.

7. The method of claim 1, wherein the at least one characteristic relates to a power spike, and wherein the predetermined threshold is related to a voltage peak exceeding a predetermined voltage threshold.

8. The method of claim 7, wherein determining at least one characteristic of the alternating current power includes determining a measured value of the alternating current power, wherein using the at least one characteristic to determine the selected branch from the plurality of branches includes determining a selected LED branch of a plurality of LED branches to route at least a portion of the alternating current power, wherein the selected LED branch is selected to dissipate the power spike.

9. The method of claim 1, wherein the at least one characteristic relates to a power spike in the alternating current power, and wherein the predetermined threshold is a predicted voltage peak of the alternating current power, wherein the predicted voltage peak is determined based on a slope on a waveform of the alternating current power at an earlier point.

10. An adaptive voltage lighting system comprising:
a zero cross detector for determining when at least one of the following changes between positive and negative: a voltage portion of alternating current power received from a power source or a current portion of alternating current power received from the power source;
phase correction circuitry that includes a plurality of circuit branches for reducing a phase displacement of the voltage portion and the current portion in the alternating current power;
a light emitting diode (LED) array coupled to the phase correction circuitry, the LED array including a plurality of LEDs to be illuminated; and
a computing device that is coupled to the phase correction circuitry, the computing device causing the adaptive voltage lighting system to perform at least the following:
utilize the zero cross detector to determine a first zero cross of the current portion of the alternating current power wherein the first zero cross includes a first timing that the current portion changes between positive and negative;
utilize the zero cross detector to determine a second zero cross of the voltage portion of the alternating current power, wherein the second zero cross includes a second timing that the voltage portion changes between positive and negative;
determine the phase displacement by comparing the first timing with the second timing;
determine whether the phase displacement meets a predetermined threshold;
in response to determining that the phase displacement meets the predetermined threshold, determine a selected circuit branch from the plurality of circuit branches, wherein the selected circuit branch creates an altered alternating current power to return the phase displacement to a level that is below the predetermined threshold; and
cause at least a portion of the altered alternating current power to illuminate at least one LED of the LED array.

11. The adaptive voltage lighting system of claim 10, further comprising:
LED control circuitry that includes a plurality of LED branches for dividing the alternating current power during a power spike; and
a peak to peak detector that determines voltage levels of at least one voltage peak on the voltage portion of the alternating current power;
wherein the computing device further causes the adaptive voltage lighting system to perform at least the following:
determine, via the peak to peak detector, a measured value of the alternating current power;
determine whether the measured value meets a threshold value;
in response to determining the measured value meets the threshold value, determining a selected LED branch of the plurality of LED branches to route at least a portion of the alternating current power, wherein the selected LED branch is determined to dissipate the power spike.

12. The adaptive voltage lighting system of claim 11, wherein determining the measured value of the alternating current power includes detecting the peak of the voltage portion.

13. The adaptive voltage lighting system of claim 11, wherein determining the measured value of the alternating current power includes predicting the peak of the voltage portion by determining a slope on the voltage portion of the alternating current power.

14. The adaptive voltage lighting system of claim 10, wherein the plurality of circuit branches each includes a resistor in series with a capacitor in series with an inductor.

15. The adaptive voltage lighting system of claim 10, wherein determining the selected circuit branch includes accessing a lookup table.

16. An adaptive voltage lighting system comprising:
light emitting diode (LED) control circuitry that includes a plurality of LED branches for dividing the alternating current power during a power spike;
a peak to peak detector that determines voltage levels of a plurality of voltage peaks on the voltage portion of the alternating current power;
an LED array coupled to the LED control circuitry, the LED array including a plurality of LEDs to be illuminated; and
a computing device that is coupled to the LED control circuitry, the computing device causing the adaptive voltage lighting system to perform at least the following:
determine, via the peak to peak detector, a measured value of the alternating current power;
determine whether the measured value meets a threshold value;
in response to determining the measured value meets the threshold value, determining a selected LED branch of the plurality of LED branches to route at least a portion of the alternating current power, wherein the selected LED branch is selected to create an altered alternating current power to dissipate the power spike; and
cause at least a portion of the altered alternating current power to illuminate at least one light emitting diode (LED).

17. The adaptive voltage lighting system of claim 16, further comprising:
a zero cross detector for determining when at least one of the following changes between positive and negative: a voltage portion of alternating current power received from a power source or a current portion of alternating current power received from the power source; and
phase correction circuitry that includes a plurality of circuit branches for reducing a phase displacement of the voltage portion and the current portion in the alternating current power;
wherein utilize the computing device is further configured to perform at least the following:
utilize the zero cross detector to determine a first zero cross of a current portion of the alternating current power wherein the first zero cross includes a first timing that the current portion changes between positive and negative;
utilize the zero cross detector to determine a second zero cross of the voltage portion of the alternating current power, wherein the second zero cross includes a second timing that the voltage portion changes between positive and negative;
determine the phase displacement by comparing the first timing with the second timing;
determine whether the phase displacement meets a predetermined threshold; and
in response to determining that the phase displacement meets the predetermined threshold, determine a selected circuit branch from the plurality of circuit branches in the phase correction circuitry, wherein the selected circuit branch creates further alters the altered alternating current power to return the phase displacement to a level that is below the predetermined threshold.

18. The adaptive voltage lighting system of claim 17, wherein the plurality of circuit branches each includes a resistor in series with a capacitor in series with an inductor.

19. The adaptive voltage lighting system of claim 17, wherein determining the selected circuit branch includes accessing a lookup table.

20. The adaptive voltage lighting system of claim 16, wherein determining the measured value of the alternating current power includes predicting the peak of the voltage portion by determining a slope at an earlier point of the alternating current power.
